(19) United States
(12) Patent Application Publication
(10) Pub. No.: US 2012/0105058 A1
(43) Pub. Date: May 3, 2012

(54) MAGNETIC FIELD SENSING

(76) Inventors: Iakov Veniaminovitch Kopelevitch, Mountain View, CA (US); Alexandre M. Bratkovski, Mountain View, CA (US)

(21) Appl. No.: 12/915,410

(22) Filed: Oct. 29, 2010

(51) Int. Cl. G01R 33/09

(52) U.S. Cl. 324/252

(57) ABSTRACT

An apparatus for magnetic field sensing, the apparatus comprising a graphitic material to exhibit a change in magneto-resistance (MR) in response to a sensed magnetic field, and a circuit in communication with the graphitic material, the circuit to receive an input from the graphitic material, the input being indicative of the MR change, and generate data corresponding to an angle of incidence for the magnetic field in response to the received input. Also disclosed is a method for magnetic field sensing, the method comprising positioning a graphitic material to sense a magnetic field, the graphitic material exhibiting a change in magneto-resistance (MR) in response to the magnetic field, and generating data corresponding to an angle of incidence for the magnetic field based on the MR change.

### BACKGROUND

Magneto-resistivity is a property of a material to change its electrical resistivity in the presence of a magnetic field. Thus, the presence of a magnetic field will cause such a material to exhibit a higher or lower electrical resistance which in turn can affect the electrical characteristics of a circuit in which the material is employed. For example, a magnetic field that causes an increase in the material's electrical resistance will result in a larger voltage drop across the material for a given current flow. Likewise, a magnetic field that causes a decrease in the material's electrical resistance will result in a smaller voltage drop across the material for the given current flow.

### BRIEF DESCRIPTION OF THE DRAWINGS

FIG. 1 illustrates an example of a sensing apparatus comprising a graphitic material;

FIG. 2 illustrates a graphitic material with a proximal magnetic field;

FIG. 3 is a graph illustrating a magneto-resistive effect for a graphitic material;

FIG. 4 is a graph illustrating another magneto-resistive effect for a graphitic material;

FIG. 5 illustrates an example of a graphitic material in communication with a measuring circuit;

FIG. 6(a) illustrates an example of measuring circuit that comprises a processor for computing the magnetic field angle based on a voltage drop signal from the graphitic material;

FIG. 6(b) illustrates an example of a lookup table relating voltage drops to magnetic field angles;

FIG. 7(a) illustrates an example of an array comprising a plurality of graphitic material samples at different angular orientations for determining magnetic field angle;

FIG. 7(b) illustrates an example of how a lookup table could be used in combination with a sensor array to determine magnetic field angle;

FIG. 7(c) illustrates an exemplary graphitic material deployed on a substrate with an adjustable angular orientation for determining magnetic field angle;

FIG. 8 illustrates an example of a graphitic magneto-resistive sensor having a plurality of planar surfaces;

FIGS. 9(a) and (b) illustrate an example of an array comprising a plurality of three-dimensional graphitic magneto-resistive sensors;

FIG. 9(c) illustrates an example of a magneto-resistor sensor array having a flexible supporting substrate; and

FIG. 10 illustrates an exemplary circuit for generating three-dimensional (3D) map data of an incident magnetic field using an array of three-dimensional magneto-resistive sensors.

### DETAILED DESCRIPTION

A graphitic material can be used as the active component in a magneto-resistive sensor, whereby a graphitic material under voltage exhibits a change in magneto-resistance (MR) in response to a sensed magnetic field. This change in MR is indicative of an angle of incidence for the sensed magnetic field, and a circuit in communication with the graphitic material can be used to measure the magnetic field's angle of incidence in response to the exhibited MR change. The result is an angle-resolved MR sensor comprising a graphitic material that can be lightweight, easy to fabricate and is capable of operating in extreme conditions, including extreme temperatures and/or pressures.

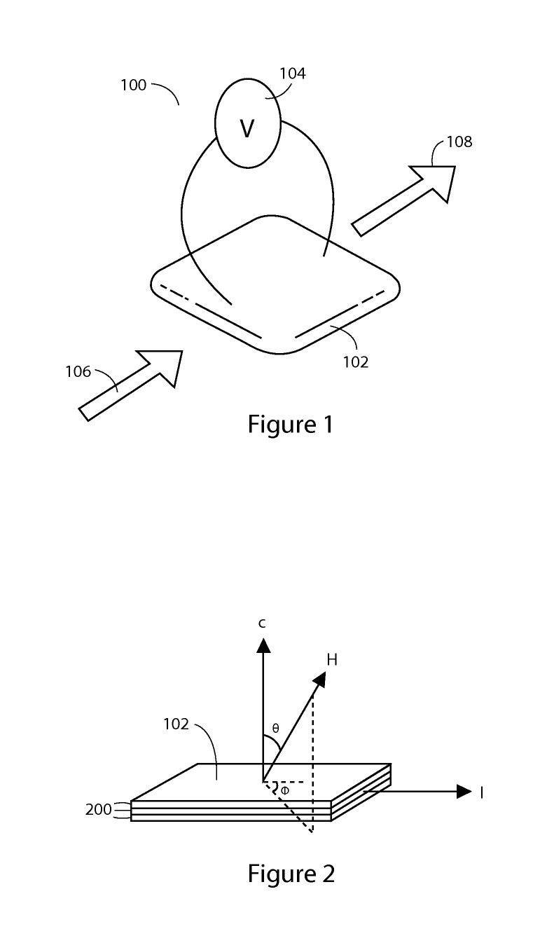

FIG. 1 generally depicts a sensing apparatus 100 comprising a graphitic material 102 through which a current flows in the direction shown by arrows 106 and 108. A voltmeter 104 in circuit with the graphitic material measures the voltage drop across the graphitic material 102. As indicated above, the presence of a magnetic field will cause the electrical resistivity of the graphitic material 102 to change, this effect being known as a magneto-resistive effect as explained above. Thus, with current flowing through the graphitic material 102, the magnetic field will cause a change in MR for the graphitic material, thereby causing a change in measurable electrical characteristics for the sensor 100. This changed electrical characteristic can take the form of a changed voltage drop across the graphitic material 102, where such voltage drop can be measured by the voltmeter 104. A current source can provide a known current, which may take the form of a constant current that is drawn by the graphitic material. With the voltage being proportional to current and resistance as per the formula V=IR, a change in MR for the graphitic material 102 can lead to a change in the R value of the formula, thereby causing a resultant change in voltage drop V for a given current I.

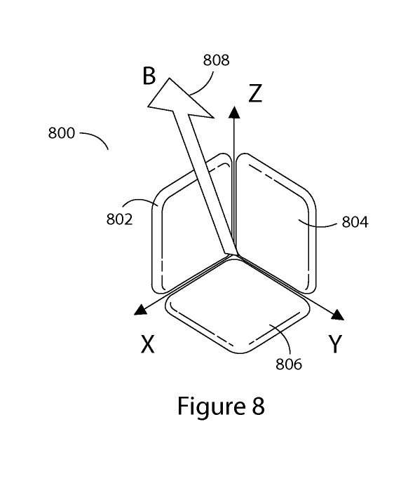

FIG. 2 illustrates an exemplary graphitic material 102 having a plurality of graphene planes 200 through which current flows. As indicated in FIG. 2, the sampling current I flows in a plane that is generally parallel with the graphene planes 200. A magnetic field H can produce an MR effect in the graphene planes 200. In this example, the magnetic field H is incident on the graphene planes 200 at an angle θ relative to the hexagonal axis c of the graphene planes (where c is generally perpendicular to the plane of current flow through the graphene planes). With graphene and other forms of graphitic materials, current flows mainly along the planar graphitic structures. With multi-layer graphene, the different graphene planes are weakly coupled to each other, so any current flowing perpendicularly between the planes is largely suppressed by the high anisotropy of the graphene (barring defects that may cause coupling between the planes). Furthermore, as described in connection with the exemplary embodiment of FIG. 8, an angle φ, shown in FIG. 2, indicative of the magnetic field orientation relative to the axis of current flow can also be sensed based on the MR effect.

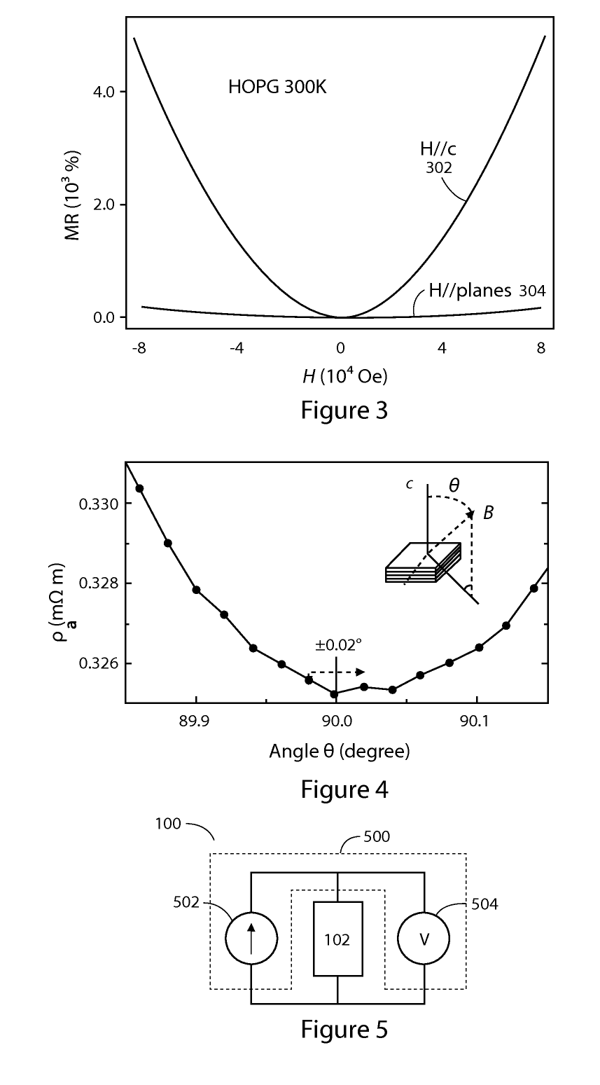

Graphitic material exhibits a magneto-resistivity that can be characterized as largely anisotropic, in which case the portion of an incident magnetic field that is perpendicular to the plane of the graphitic material in which current flows is what contributes to the MR effect. That is, generally speaking the component of H that is parallel with c (H//c) is the contributor to the MR effect. FIG. 3 generally illustrates this property with respect to a highly-oriented pyrolytic graphite (HOPG) sample. The vertical axis of this figure marks the MR effect for the HOPG sample at a temperature of around 300 K with magnetic fields of varying strengths applied perpendicular to the plane in which current flows through the HOPG sample (denoted by the H//c plot 302) and parallel with the plane in which current flows through the HOPG sample (denoted by the H//planes plot 304). This strong MR anisotropy is believed to be due to layered quasi-two-dimensional (2D) structure of graphite in the form of a stack of weakly coupled graphene layers. A finite but very small MR measured for the magnetic field planes parallel to the plane of current flow through the graphitic material is believed to be an artifact of a sample mosaicity characterized by a finite FWHM (full width at half maximum of x-ray rocking curves). In other words, the geometrical MR of graphitic material is believed to originate from the field misalignment, responsible for a finite H⊥ contribution. Hence, MR in graphitic materials is essentially the orbital effect. Carriers (electrons and holes) in graphitic materials generally exhibit very high in-plane mobility (μ>10⁵ cm²/V·s) and hence very large MR (˜(μH)ⁿ, for n≦2).

As a result of the anisotropic nature of MR for graphitic materials, there is an angular dependence of the MR effect for graphitic materials whereby the graphitic material's MR effect is affected by the angle between the direction of electrical current through the material and the orientation of the incident magnetic field. FIG. 4 generally illustrates this property with respect to an HOPG sample. The vertical axis of FIG. 4 corresponds to the in-plane resistivity of the HOPG sample, while the horizontal axis of FIG. 4 corresponds to the angle θ of the magnetic field B relative to the plane c (see FIG. 2). The measurements are for a magnetic field of 9 Tesla (T) and a temperature of 2 K. As can be seen, the resistivity of the HOPG sample was at a minimum when the magnetic field was aligned in parallel with the plane of current flow within the HOPG sample (when the angle θ is approximately 90°). As the angle θ increasingly deviates from 90°, it can be seen that the in-plane resistivity also increases. Thus, larger voltage drops across the graphitic material 102 are expected if the angle θ for the magnetic field H relative to c increasingly deviates from 90°.

An example of graphitic material that can be advantageously employed in an angle-resolved MR sensor is highly ordered graphite (HOG), an example of which is HOPG. Additional examples of graphitic materials for use in an angle-resolved MR sensor include high quality natural graphite (NG), Kish graphite (KG), multilayer graphene (MLG) (e.g., epitaxial MLG grown on an SiC substrate), and mono-crystalline graphite. The graphitic material 102 used in the sensor 100 can be deployed in a largely planar arrangement wherein the length and width of the graphitic material are much larger than its thickness, and where the direction of current flow through the graphitic material will largely be in a plane parallel with the length or width of the graphitic material. An example of dimensions that could be employed for the graphitic material 102 are on the order of a length, width and thickness respectively of 1 mm³×1 mm³×0.1 mm³. However, larger and/or smaller dimensions could be used. Regarding smaller dimensions of thickness, the minimum thickness can be a thickness at which the graphitic material still exhibits stability. To fabricate the graphitic material, a larger block of graphite can be cleaved with a razor or the like into graphite flakes with thinner dimensions that exhibit a planar shape as noted above. Electrodes can then be attached to the graphitic material 102 to provide conduits for measurement. Four electrodes arranged in a 4-point probing technique can be used in this regard.

The graphitic material can be packaged in any of a number of ways for use as an MR sensor, including deposition on a supporting substrate, glass packaging, or other packaging within a magnetically transparent material.

As shown in FIG. 5, a measuring circuit 500 can be in communication with the graphitic material 102 to process the changed electrical characteristics for the sensor 100 arising from the MR change for use in measuring a characteristic such as an angle of incidence for an incident magnetic field. As explained hereinafter, such a measuring circuit can be used to generate data corresponding to the angle of the magnetic field relative to some reference. In the example described herein, the frame of reference is the axis c shown in FIG. 2. However, it should be understood that other frames of reference could be employed. For example, the magnetic field angle could be measured relative to the plane in which current flows through the graphitic material (which would translate to a 90° offset relative to the c frame of reference).

The measuring circuit 500 may comprise a current source 502 and a voltmeter 504, wherein the current source 502 delivers a known current to the graphitic material 102 and the voltmeter 504 measures the voltage drop across the graphitic material 102. This voltage drop measurement comprises data corresponding to a magnetic field angle (see FIG. 4).

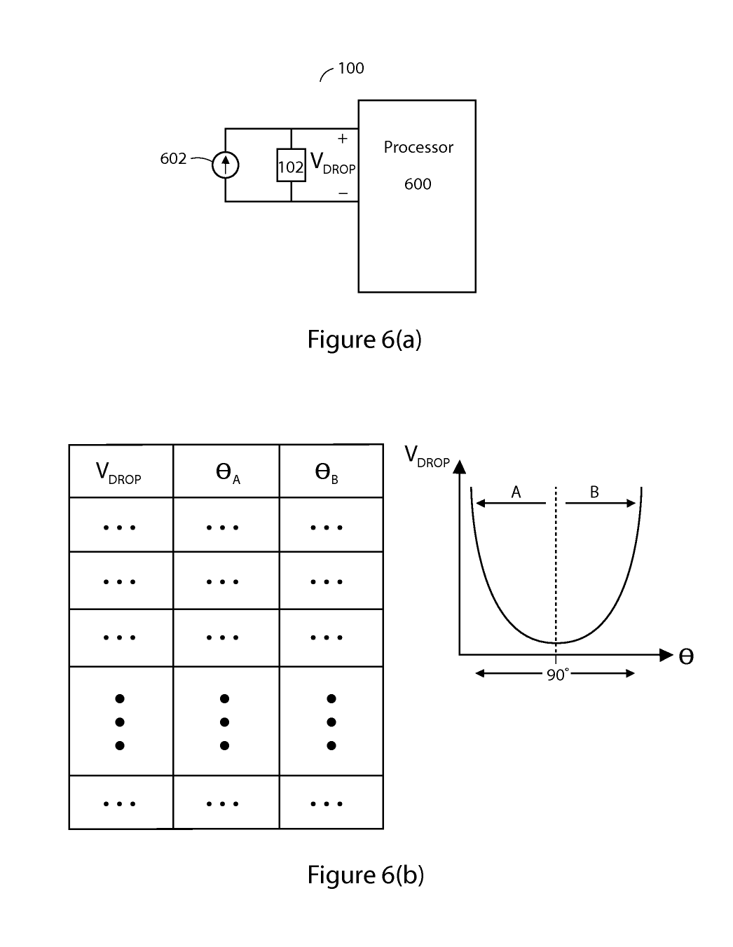

Furthermore, the measuring circuit 500 may comprise a processor and associated memory, where the processor computes data relating to the magnetic field angle based on input data (whether in analog or digital form) representative of the voltage drop across the graphitic material 102. FIG. 6(a) depicts an example of a sensor 100 where a processor 600 includes embedded voltmeter capabilities (including any necessary analog-to-digital conversion of the voltage drop signal). However, it should be understood that the sensor 100 could also include a standalone voltmeter 504 that provides a voltage drop measurement as an input to the processor 600 if desired.

The processor 600 can be programmed to process the voltage drop information to generate more refined data indicative of the magnetic field angle. Toward this end, a lookup table such as the one in FIG. 6(b) can be employed. In these examples it will be assumed that the magnetic field H is quasi-static, in which case the magnitude of the magnetic field H will change slowly but the direction of the magnetic field H may vary more significantly. As such, it will be assumed that the dominant contributor to the MR change exhibited by the graphitic material 102 will be the magnetic field angle rather than the magnetic field strength.

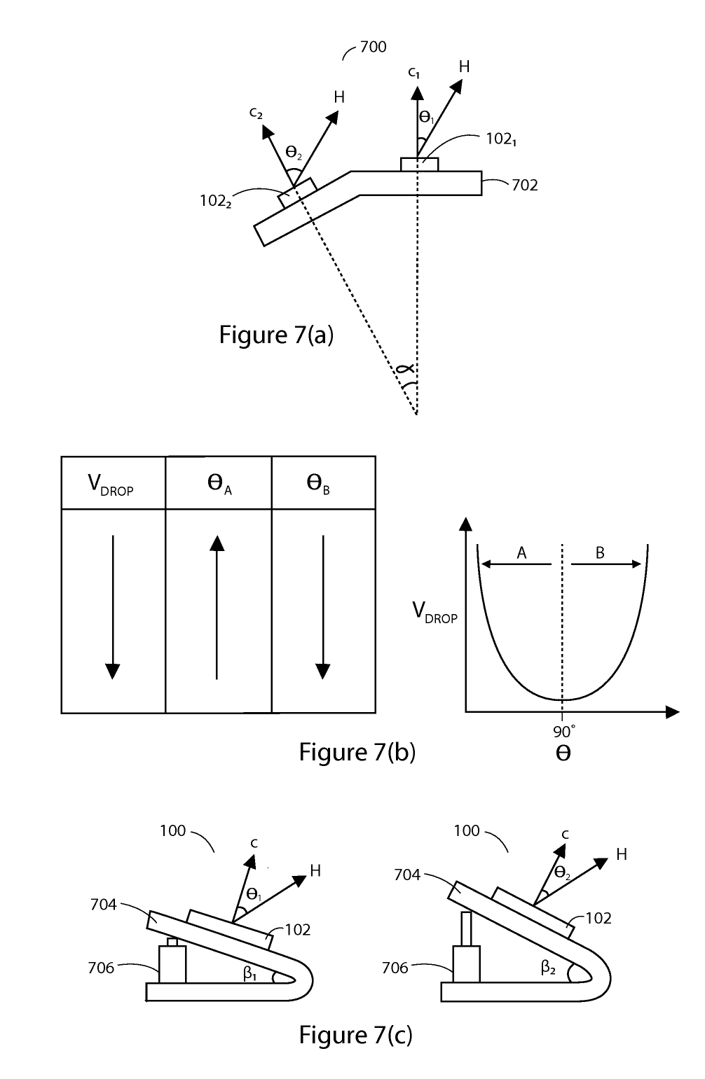

Prior to use in a sensor, a graphitic material 102 can be calibrated by applying a magnetic field having a known strength and orientation to the graphitic material and measuring the voltage drop across the graphitic material as the angular orientation of the graphitic material relative to the magnetic field is varied in known increments. A plot similar to the one shown in FIG. 4 can then be created that relates the measured voltage drop to the angle θ. Such a plot is expected to exhibit the general U-shape shown in FIG. 4 where the voltage drop increases for increasing deviations of the angle θ relative to 90°. Given this general U-shape, it is further expected that a given voltage drop will correspond to two magnetic field angle options, θ_{A} and θ_{B}, where the θ_{A} angles refer to the left branch of the general U-shape of the plot and the θ_{B} angles refer to the right branch of the general U-shape of the plot (see FIG. 7(b)). The exemplary lookup table shown in FIG. 6(b) can store the values of θ_{A} and θ_{B} for different given voltage drops. During operation, when the graphitic material 102 is used as a magnetic field sensor, the processor 600 can perform a lookup in the table based on the measured voltage drop to retrieve the θ_{A} and θ_{B} values.

If it is desired to further resolve the magnetic field angle to one of these two options, any of a number of techniques that break the general symmetry of the voltage drop/angle θ relationship can be employed. One such example is shown in FIG. 7(a). In this example, a plurality of graphitic material samples 102₁ and 102₂ are positioned on a substrate 702 such that at least two samples have different angular orientations relative to each other. As shown in FIG. 7(a), there is a bend in the supporting substrate 702 such that there is an offset corresponding to the angle α between θ₁ and θ₂. Given this orientation it is known that θ₂ is greater than θ₁ by about the value of angle α.

Thus, if the voltage drops across the two graphitic samples are simultaneously measured (V_{DROP1} for graphitic sample 102₁ and V_{DROP2} for graphitic sample 102₂), then inferences can be drawn that permit one to select between the left leg and right leg of the voltage drop versus angle θ plot to determine a specific value for the magnetic field angle. FIG. 7(b) illustrates the general relationship between the V_{DROP}, θ_{A} and θ_{B} values. As the voltage drop increases (shown by the arrow within the V_{DROP} column of FIG. 7(b), it can be seen from the plot shown in FIG. 7(b) that the values for angle θ_{A} Will get smaller (shown by the arrow within the θ_{A} column of FIG. 7(b)). Furthermore, as the voltage drop increases, it can also be seen from the plot shown in FIG. 7(b) that the values for angle θ_{B} will get larger (shown by the arrow within the θ_{B} column of FIG. 7(b)). Assuming that the difference in magnetic field strength and angle at the locations corresponding to the two graphitic samples 102₁ and 102₂ have negligible impact on the measured voltage drops, one would expect V_{DROP2} across graphitic sample 102₂ to be greater than V_{DROP1} across graphitic sample 102₁ if the magnetic field angle falls within the θ_{B} column of FIG. 7(b) because by definition θ₂ is greater than θ₁ (which is the voltage pattern corresponding to the θ_{B} column). Likewise, one would expect V_{DROP2} across graphitic sample 102₂ to be less than V_{DROP1} across graphitic sample 102₁ if the magnetic field angle falls within the θ_{A} column of FIG. 7(b) by virtue of the known θ₂-θ₁ relationship. As such, the processor 600 can be programmed with logic that selects as between the θ_{A} and θ_{B} columns of the lookup table using the following logic (premised on the condition θ₂>θ₁):
If V_{DROP2}>V_{DROP1}, then select the magnetic field angle θ from the θ_{B} column of the lookup table
Else, then select the magnetic field angle θ from the θ_{A} column of the lookup table
   If desired, separate lookup tables can be maintained for each graphitic material sample 102 in the sensor array 700. In such a scenario, it is expected that the resolved angle as determined from the two lookup tables will be approximately equal in value. Thus, in the example of FIG. 7(a), if separate lookup tables were maintained for both sample 102₁ and sample 102₂, the processor can be programmed to simply select one of resolved angle values from the two tables. Alternatively, the processor can be programmed to return the magnetic field angle as the average between the two resolved angle values from the two tables. Further still, to the extent that the measured voltage drop does not correspond to a V_{DROP} entry in the lookup table, the processor can be programmed to interpolate angle values from the two closest V_{DROP} entries in the lookup table using a line/curve fitting technique or the like (e.g., linear interpolation, polynomial interpolation, etc.).

FIG. 7(c) depicts an example where a single graphitic material sample 102 is used with a symmetry breaking technique to resolve between the θ_{A} and θ_{B} columns of the lookup table. In this example, a rocking technique can be used in conjunction with multiple voltage drop measurements. In this example, one will assume that the voltage measurements are taken sufficiently close to each other in time for any change in magnetic field angle to be negligible. To provide the desired rocking or tilting action, the graphitic material sample 102 can be positioned on a substrate 704 that includes a tilting device 706 that is configured to elevate one end of the graphitic sample 102 and thus modify the angle θ between magnetic field H and the axis c. This is shown by way of example in FIG. 7(c) where tilt device 706 comprises an adjustable arm that can raise one end of the sensor by an angle β. In this example, where the angle of β is adjusted by the arm from a value of β₁ to β₂, where β₂ is greater than β₁, it can be seen that the angle θ will decrease (where θ₂ is less than θ₁). Once again, by knowing the relationship between θ₁ and θ₂, one can resolve whether the magnetic field angle falls within the θ_{A} or θ_{B} column of the lookup table. In this example where θ₂<θ₁, it follows that the magnetic field angle will fall in the θ_{A} column of FIG. 7(b) if V_{DROP2} is greater than V_{DROP1} and that the magnetic field angle will fall in the θ_{B} column of FIG. 7(b) if V_{DROP2} is less than V_{DROP1}.

Also, while in the examples mentioned above the processor is configured to determine the angle θ, it should be understood that the processor can also or alternatively be configured to compute other data corresponding to the magnetic field angle, such as the change in magnetic field angle, Δθ, over time by determining the differences between successive angle determinations over time.

As another example, a graphitic magneto-resistive sensor can be formed from multiple planar surfaces of graphitic material, as shown by FIG. 8. The sensor 800 of FIG. 8 comprises a first planar surface 802 formed from graphitic material, a second planar surface 804 formed from graphitic material and a third planar surface 806 formed from graphitic material, wherein the first, second and third planar surfaces are arranged perpendicularly with respect to each other within a degree of tolerance, e.g., a 1%-2%. In this example, each graphitic planar surface 802, 804 and 806 would correspond to a graphitic material sample 102 such as that shown in FIG. 2. As shown in FIG. 8, planar surface 802 is arranged in the xz-plane, planar surface 804 is arranged in the yz-plane, and planar surface 806 is arranged in the xy-plane. With such an architecture, each planar surface can be used to measure an angle of incidence for an incident magnetic field B (808), and from these measurements, a plurality of characteristics of the magnetic field B in three-dimensional (3D) space can be determined. For example, if each planar surface senses the angle θ relative to the plane of current flow through that surface, these angular measurements can be combined to determine a direction for the magnetic field B in 3D space. Further still, other characteristics such as the gradient of the magnetic field B in 3D space can be measured (e.g., by moving the sensor along the x-, y-, and z-axes to detect the spatial variance in magnetic field).

With such an architecture, each graphitic planar surface 802, 804 and 806 can have electrodes attached thereto (e.g., a 4-probe arrangement). With current flowing through the graphitic planar surfaces, the electrodes can be used to measure the MR change exhibited by the graphitic planar surface 802, 804 or 806 in response to the incident magnetic field B. If desired a single current source can be employed to provide the current to the different graphitic planar surfaces of the sensor, although this need not be the case. For example, each graphitic planar surface could have its own current source.

The angle of incidence θ for each planar surface can be measured as described above, and from these measurements, the direction of the magnetic field can be determined in 3D space. Using a frame of reference of the c axis for the angular measurements, one can define c_{xz} as the perpendicular plane for the direction of current flow in graphitic planar surface 802, c_{yz} as the perpendicular plane for the direction of current flow in graphitic planar surface 804, and c_{xy} as the perpendicular plane for the direction of current flow in graphitic planar surface 806. With this reference, the angles θ_{xz}, θ_{yz} and θ_{xy} (where θᵢⱼ is the angle between the magnetic field B and cᵢⱼ) measured by the sensor will define the direction of the magnetic field in 3D space.

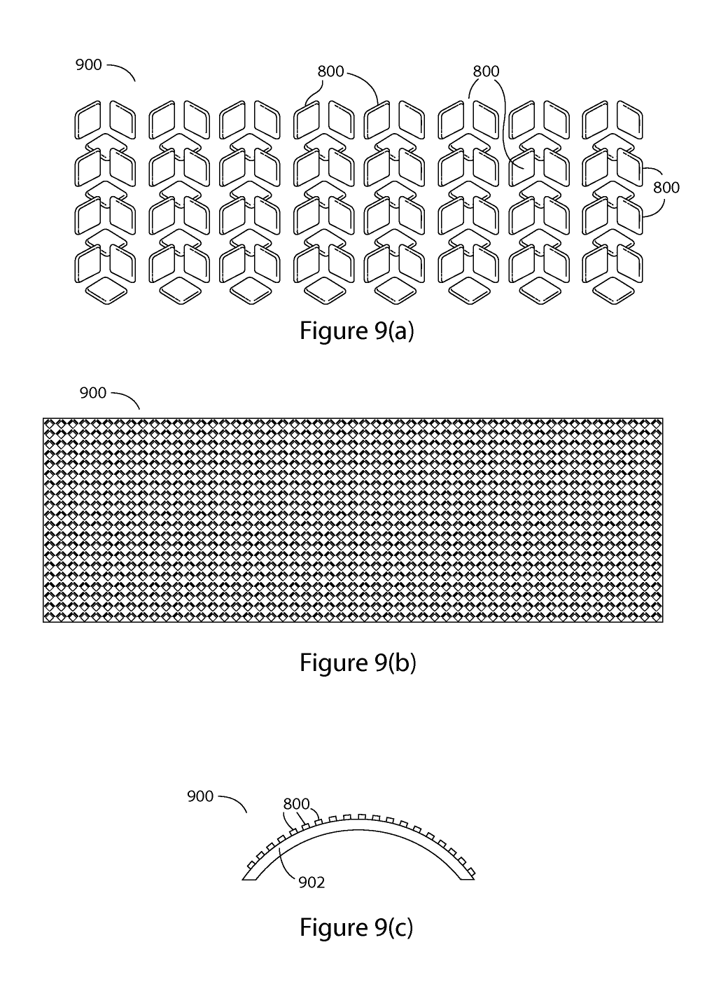

The 3D magneto-resistive sensor 800 of FIG. 8 can be deployed in an array 900 comprising a plurality of such sensors 800, as shown in FIG. 9(a). The number of sensors 800 deployed in such an array can be variable and reach upwards to the hundreds or thousands (or more) of such sensors 800 depending upon the desired application and resolution. In this example, a plurality of 3D magneto-resistive sensors 800 are arranged in a grid pattern or the like, as shown in FIG. 9(b) which illustrates a top view of an array comprising numerous ones of sensors 800. The sensors can be positioned on a supporting substrate or the like. Each sensor's measurements can then serve as a characterization of the sensed magnetic field at a position corresponding to the location of that sensor in the array. From these measurements, a detailed 3D map of a magnetic field can be derived. For example, a gradient map of a magnetic field can be generated by feeding the spatially-resolved voltage drop measurements of the sensors to a processor to compute the values δB/δx, δB/δy, and δB/δz. Furthermore, a processor can be configured to compute other maps of the magnetic field from the spatially-resolved voltage drop measurements in the 3D planes, such as maps of magnitude and direction over time.

In another example, the sensors 800 can be positioned on a flexible substrate 902 as shown in FIG. 9(c). By employing a flexible supporting substrate 902, the array can be manipulated to assume a desired shape that fits over a complex surface. Thus, if its desired to measure a magnetic field characteristic produced by a material having a sphere-like or cylinder-like shape, the array shown in FIG. 9(c) could be manipulated to effectively wrap around the material to obtain the voltage drop measurements for use in producing a desired magnetic field map corresponding to that material.

Also, while in the example of FIG. 9(b), the sensors are arranged in a grid pattern, other sensor patterns on the array can be employed. For example, a stripe array could be used.

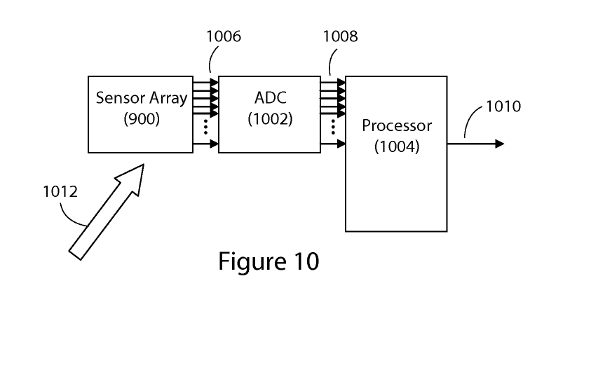

As shown in FIG. 10, such an array 900 can be in communication with an analog-to-digital converter (ADC) 1002 that digitizes analog signals 1006 generated by the sensors 800 in the array, where these analog signals are representative of the MR changes caused by the incident magnetic field 1012. A processor 1004 can receive the digital outputs 1008 of the ADC 1002 and process these digital outputs to compute desired map data, for example direction and gradient information for the magnetic field in 3D space as noted above. Each digitized reading from a sensor can be mapped to a particular position in the grid by the processor 1006 to support such mapping. Also, in an example where the processor 1004 includes its own ADC capabilities, a circuit can omit the standalone ADC 1002.

The graphitic magneto-resistive sensors described herein are amenable to numerous advantageous applications, including usage in sensor networks where magnetic fields are expected to be present. For example, one could employ one or more graphitic magneto-resistive sensors to measure the remanent magnetization in a ferromagnetic material by bringing the sensor(s) into proximity with the ferromagnetic material. As another example, one or more sensors could be used to measure the distribution of stray magnetic field over the ferromagnetic material (either by using an array comprising a plurality of graphitic magneto-resistive sensors or by moving a graphitic magneto-resistive sensor around the ferromagnetic material). As yet another example, one or more graphitic magneto-resistive sensors could be employed to measure trapped magnetic flux in superconductors. Furthermore, due to the selection of a graphitic material as the active component in the magneto-resistive sensor, such sensors can operate in extreme conditions and harsh environments (e.g., with either low or high ambient temperatures as well as high pressures) because graphitic materials can be sustained in such environments without significant degradation all while still exhibiting an MR effect. When graphite is protected from oxygen (e.g., in a vacuum or in an inert atmosphere), it can operate up to around 3000° C. Given the graphitic material's stability and durability in extreme and harsh environments, the graphitic magneto-resistive sensors can be employed in natural resources explorations, whether underground or undersea. Further still, given its carbon base, such graphitic magneto-resistive sensors can also be employed in sensitive environments such as within biological tissues to sense incident magnetic fields. Moreover, the use of graphitic material is not expected to place any effective limitations on the sensor's operational rate as the graphitic material is expected to exhibit fast magnetic response times.

While specific embodiments of the invention have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of invention which is to be given the full breadth of the claims appended and any and all equivalents thereof. It should further be understood that the embodiments disclosed herein include any and all combinations of features as disclosed herein and/or described in any of the dependent claims.

What is claimed is:

1. An apparatus for magnetic field sensing, the apparatus comprising:
a graphitic material to exhibit a change in magneto-resistance (MR) in response to a sensed magnetic field; and
a circuit in communication with the graphitic material, the circuit to receive an input from the graphitic material, the input being indicative of the MR change, and generate data corresponding to an angle of incidence for the magnetic field in response to the received input.

2. The apparatus of claim 1 wherein the graphitic material comprises at least one member selected from the group consisting of highly ordered graphite (HOG), highly ordered pyrolytic graphite (HOPG), multi-layer graphene (MLG), natural graphite (NG), Kish graphite (KG), and mono-crystalline graphite.

3. The apparatus of claim 1 wherein the graphitic material has a planar shape, and wherein the MR change exhibited by the graphitic material comprises an anisotropic MR change.

4. The apparatus of claim 3 wherein the graphitic material comprises a first graphitic material and a second graphitic material, wherein the first and second graphitic materials are positioned with a known angular orientation offset relative to each other.

5. The apparatus of claim 4 wherein the circuit comprises a processor, the processor to receive input data corresponding to a voltage across the first graphitic material and a voltage across the second graphitic material, and determine the magnetic field angle of incidence based on the received input data.

6. The apparatus of claim 5 wherein the processor is to access a lookup table that relates a plurality of voltage values with a plurality of angle of incidence values to determine the magnetic field angle of incidence, wherein the lookup table comprises a plurality of voltage values that each correspond to a plurality of magnetic field angles of incidence, and wherein the processor is further to select from the plurality of magnetic field angles of incidence in the lookup table corresponding to a given voltage input as a function of the known angular orientation offset between the first and second graphitic materials.

7. The apparatus of claim 1 further comprising a tilt device to change an angular orientation of the graphitic material between a first measurement and a second measurement, and wherein the circuit is to determine a magnetic field angle of incidence based on the first measurement, the second measurement and the changed angular orientation.

8. The apparatus of claim 1 wherein the graphitic material comprises a first planar surface, a second planar surface and a third planar surface, wherein the first, second and third planar surfaces are substantially perpendicular with respect to each other, and wherein the circuit is further to generate data indicative of a direction for the magnetic field in three-dimensional space.

9. A method for magnetic field sensing, the method comprising:
positioning a graphitic material to sense a magnetic field, the graphitic material exhibiting a change in magneto-resistance (MR) in response to the magnetic field; and
generating data corresponding to an angle of incidence for the magnetic field based on the MR change.

10. The method of claim 9 further comprising:
obtaining a first voltage measurement across the graphitic material;
changing an angular orientation of the graphitic material;
obtaining a second voltage measurement across the graphitic material after the changing of the graphitic material's angular orientation; and
wherein the generating comprises determining an angle of incidence for the magnetic field based on the first voltage measurement, the second voltage measurement and the changed angular orientation.

11. An apparatus for magnetic field sensing, the apparatus comprising:
an array comprising a plurality of graphitic magneto-resistive sensors, each of the plurality of graphitic magneto-resistive sensors comprising a first planar surface, a second planar surface and a third planar surface, wherein the first, second and third planar surfaces are arranged substantially perpendicularly with respect to each other, and exhibit a change in magneto-resistance (MR) in response to a sensed magnetic field, wherein the array is to sense a plurality of characteristics of the magnetic field in three-dimensional space based on the MR changes exhibited by the magneto-resistive sensors.

12. The apparatus of claim 11 further comprising a circuit to receive data representative of the sensed characteristics and compute a gradient map for the magnetic field based on the received data.

13. The apparatus of claim 11 further comprising a circuit to receive data representative of the sensed characteristics and compute a direction map for the magnetic field based on the received data.

14. The apparatus of claim 11 wherein each magneto-resistive sensor is to generate a signal indicative of a direction for the magnetic field in three-dimensional (3D) space, the apparatus further comprising a circuit to receive the signals from the magneto-resistive sensors and map each signal to a position in the array.

15. The apparatus of claim 11 wherein the array comprises a flexible substrate on which the plurality of graphitic-magnetic resistive sensors are positioned, wherein the flexible substrate is manipulable to assume a plurality of shapes.
